(19) United States
(12) Patent Application Publication
(10) Pub. No.: US 2015/0187686 A1
(43) Pub. Date: Jul. 2, 2015

(54) SEMICONDUCTOR DEVICE

(71) Applicant: KABUSHIKI KAISHA TOYOTA JIDOSHOKKI, Kariya-shi (JP)

(72) Inventors: Shogo MORI, Aichi-ken (JP); Yuri OTOBE, Aichi-ken (JP); Shinsuke NISHI, Aichi-ken (JP)

(73) Assignee: KABUSHIKI KAISHA TOYOTA JIDOSHOKKI, Kariya-shi (JP)

(21) Appl. No.: 14/577,338

(22) Filed: Dec. 19, 2014

(30) Foreign Application Priority Data
Dec. 26, 2013 (JP) 2013-270528

(51) Int. Cl. H01L 23/495

(52) U.S. Cl. CPC H01L 23/49568; H01L 23/4952

(57) ABSTRACT

There is provided a semiconductor device that includes a circuit board, a semiconductor element mounted to the circuit board, a control signal terminal disposed on the opposite side of the semiconductor element from the circuit board, and a bonding wire connecting the semiconductor element and the control signal terminal.

### BACKGROUND OF THE INVENTION

The present invention relates to a semiconductor device.

Japanese Patent Application Publication No. 2003-289085 discloses a semiconductor device that is used as an inverter that is one of electronic devices and drives a traction motor of an electric vehicle.

As shown in the drawings of the cited publication, the semiconductor device has a semiconductor element and an external lead that are connected each other by an aluminum bonding wire.

In connecting the semiconductor element and the eternal lead by wire bonding, the semiconductor device needs to have a space that permits the use of tools for the bonding operation. On the other hand, electronic devices such as semiconductor devices are required to be smaller in size because electronic apparatuses in which such electronic devices are to be mounted are also required to be made smaller in size.

The present invention, which has been made in light of the above problem, is directed to providing a semiconductor device that can be made smaller in size.

### SUMMARY OF THE INVENTION

In accordance with an aspect of the present invention, there is provided a semiconductor device that includes a circuit board, a semiconductor element mounted to the circuit board, a control signal terminal disposed on the opposite side of the semiconductor element from the circuit board, and a bonding wire connecting the semiconductor element and the control signal terminal.

Other aspects and advantages of the invention will become apparent from the following description, taken in conjunction with the accompanying drawings, illustrating by way of example the principles of the invention.

### BRIEF DESCRIPTION OF THE DRAWINGS

The invention together with objects and advantages thereof, may best be understood by reference to the following description of the presently preferred embodiments together with the accompanying drawings in which:

FIG. 1 is a front view of a semiconductor device according to an embodiment of the present invention;

FIG. 2 is a fragmentary plan view of the semiconductor device of FIG. 1; and

FIG. 3 is a plan view of a semiconductor device according to a background art.

### DETAILED DESCRIPTION OF THE EMBODIMENTS

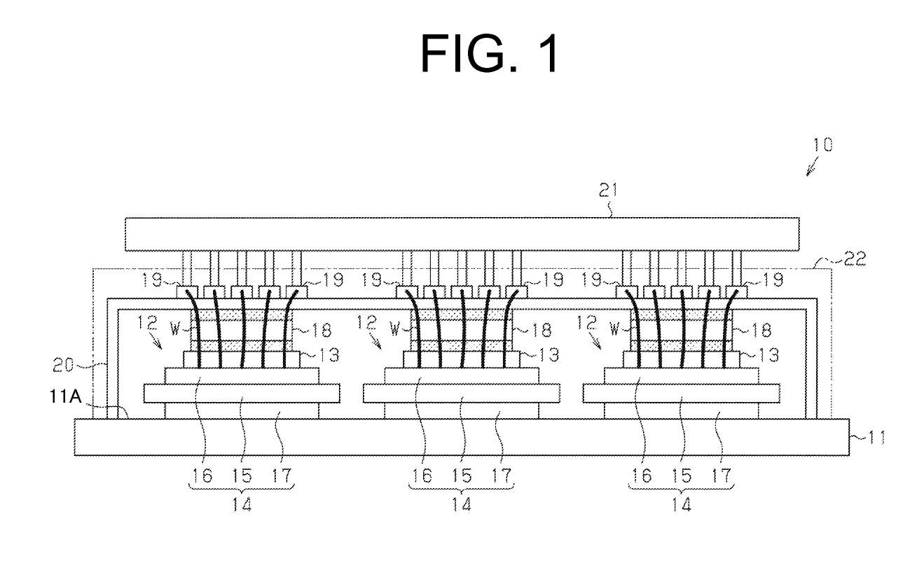

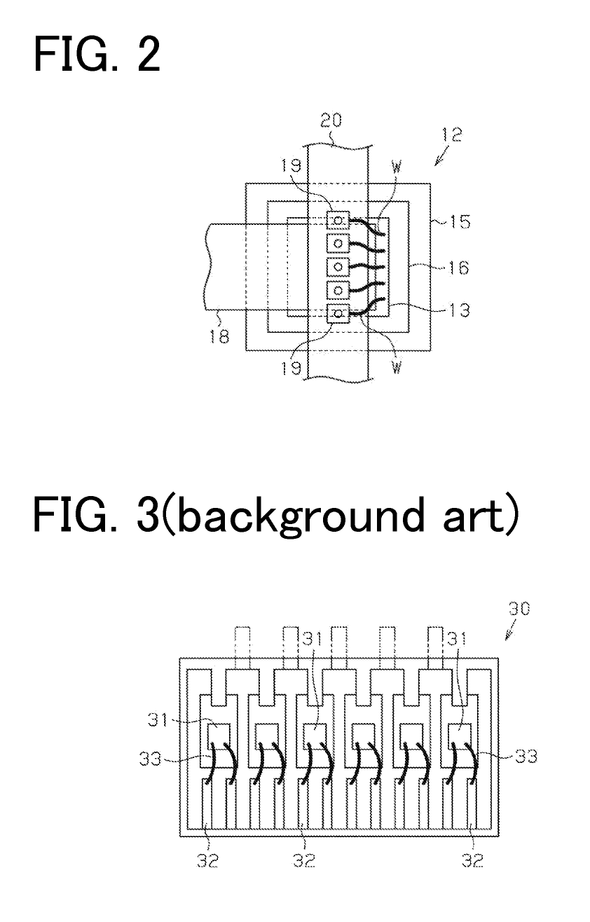

The following will describe a semiconductor deice according to an embodiment of the invention with reference to FIGS. 1 and 2. As shown in FIG. 1, the semiconductor device that is designated by reference numeral 10 includes a radiator 11 and a semiconductor module 12. The radiator 11 includes a mounting portion 11A on which the semiconductor module 12 is mounted and serves to radiate the heat generated by the semiconductor module 12 mounted on the mounting portion 11A. The radiator 11 in the semiconductor device 10 according to the present embodiment is of a plate shape and made of copper, aluminum or ceramic.

A plurality of semiconductor modules 12 is mounted on the radiator 11. The semiconductor module 12 has a semiconductor element 13 and a circuit board 14 on which the semiconductor element 13 is mounted. The semiconductor element 13 is a switching element such as an IGBT (Insulated Gate Bipolar Transistor).

The circuit board 14 includes a ceramic board 15 serving as an insulation layer, a first metal plate 16 connected on the first surface of the ceramic board 15 and serving as a wiring layer, and a second metal plate 17 connected on the second surface of the ceramic board 15 that is opposite from the first surface and serving as a junction layer. The semiconductor element 13 is soldered to the first metal plate 16. The second metal plate 17 is brazed to the radiator 11, so that the circuit board 14 is connected to the radiator 11. The ceramic board 15 is made of, for example, aluminum nitride. The first metal plate 16 and the second metal plate 17 are made of, for example, pure aluminum such as aluminum for industrial use having 99.0% purity or higher, or copper.

As shown in FIGS. 1 and 2, a power terminal 18 for supplying main current to the semiconductor element 13 is disposed above the semiconductor element 13 of each semiconductor module 12. The power terminal 18 is located immediately above the semiconductor element 13 and electrically connected to the semiconductor element 13. A control signal terminal 19 is disposed above the semiconductor element 13 of the semiconductor module 12. The control signal terminals 19 are mounted side by side on a terminal base 20 that is fixed to the radiator 11. The control signal terminal 19 thus mounted on the terminal base 20 is disposed above the power terminal 18. Thus, the power terminal 18 is located between the semiconductor element 13 and the control signal terminal 19. In the semiconductor device 10 according to the present embodiment, the power terminal 18 and the control signal terminal 19 are located above the semiconductor module 12 and these terminals 18, 19 are stacked on the semiconductor module 12.

The plural control signal terminals 19 are provided for each semiconductor module 12 and disposed side by side at mounting positions on the terminal base 20 for the respective semiconductor modules 12 to transmit signals to the semiconductor modules 12. Each semiconductor element 13 is electrically connected to its corresponding control signal terminals 19 by bonding wires W. In the present embodiment, the bonding wires W extend upward because the control signal terminals 19 are located above the semiconductor element 13. The control signal terminal 19 for each semiconductor module 12 are electrically connected to a control board 21 disposed above the semiconductor module 12. In the present embodiment, the control board 21 is formed by a single board.

The semiconductor device 10 has a resin member 22 that is provided to cover electronic components including the semiconductor module 12, the power terminal 18 and the control signal terminal 19. It is noted that a part of the control signal terminal 19 is exposed from the resin member 22 without being covered by the resin member 22 and connected to the control board 21. That is, at least a part of the control signal terminal 19 that is bonded by the bonding wire W may be sealed by the resin member 22.

The following will describe the operation of the semiconductor device 10. The disposition of the control signal terminal 19 above the semiconductor element 13 provides a space required in connecting the semiconductor element 13 and the control signal terminal 19 by wire bonding in vertical direction of the semiconductor device 10. During the bonding, tools for connecting the bonding wires are provided in the above-cited space. As shown in FIG. 2, the terminal base 20 is spaced in the plane direction at a distance from the connection between the semiconductor element 13 and the bonding wire W. Therefore, a space is formed between the semiconductor element 13 and the control signal terminal 19 above the semiconductor element 13 and such space is used for bonding.

The present embodiment offers the following advantageous efforts.

(1) The disposition of the control signal terminal 19 above the semiconductor element 13 shortens the distance between the semiconductor element 13 and the control signal terminal 19. Accordingly, the length of the bonding wire W connecting the semiconductor element 13 and the control signal terminal 19 can be shortened and the semiconductor device 10 can be made small in size.

(2) A space for bonding may be disposed above the semiconductor element 13. That is, the space required for bonding may be provided in the vertical direction of the semiconductor device 10. As a result, the semiconductor device 10 can be made small in size.

(3) The provision of the resin member 22 serves to prevent delamination from occurring at the connection where the semiconductor element 13 and the circuit board 14 are connected and also where the circuit board 14 and the radiator 11 are connected, due to thermal stress. As a result, the reliability of the semiconductor device 10 can be improved. Furthermore, the part of the bonding wire W at which the semiconductor element 13 and the control signal terminal 19 are connected is also covered by the resin member 22. As a result, disconnection of the bonding wire W hardly occurs and the vibration resistance of the semiconductor device 10 is improved.

(4) The disposition of the control board 21 controlling the semiconductor element 13 above the semiconductor element 13 allows the semiconductor device 10 to be made mall in size.

(5) The disposition of the power terminal 18 between the semiconductor element 13 and the control signal terminal 19 permits the power terminal 18 to be used to support the control signal terminal 19. As a result, the vibration resistance of the semiconductor device 10 is improved.

(6) The power terminal 18, which is interposed between the semiconductor element 13 and the control signal terminal 19, serves as a support base for the bonding operation, which helps facilitate the bonding operation.

(7) Such disposition of the power terminal 18 provides good insulation of the semiconductor element 13, so that the length of the bonding wire W connecting between the semiconductor element 13 and the control signal terminal 19 can be shortened and the semiconductor device 10 can be made small in size.

The present embodiment may be modified as follows. The power terminal 18 may not be disposed above the semiconductor element 13. For example, the power terminal 18 may be disposed side by side with the semiconductor element 13.

The connecting method in connecting the semiconductor module 12 to the circuit board 14 includes fastening by a bolt, pressure welding and so on. The radiator 11 may be a cooling device having therein a passage through which refrigerant is flowed. In this case, since the control signal terminal 19 is disposed above the semiconductor element 13, no cooling device needs to be disposed immediately below the control signal terminal 19 that needs not to be cooled. Therefore, the cooling device is prevented from being large in size and the semiconductor device 10 can be made small in size.

The control signal terminal 19 may be disposed immediately above the power terminal 18. In this case, the terminal base 20 is dispensed with and the insulation between the power terminal 18 and the control signal terminal 19 may be ensured by any resin layer.

The semiconductor device 10 may dispense with the resin member 22. The arrangement of the control board 21 may be changed as required. The second metal plate 17 that forms a part of the circuit board 14 may serve as a part to reduce the stress applied to the connection by which the semiconductor element 13 and the circuit board 14 are connected and also the connection by which the circuit board 14 and the radiator 11 are connected. In this case, the second metal plate 17 may have therein a space in the form of a step, a groove or a recess forming a part of the second metal plate 17 that is not connected to the radiator 11 and hence helps reduce or relieve the thermal stress.

What is claimed is:

1. A semiconductor device comprising:
a circuit board;
a semiconductor element mounted to the circuit board;
a control signal terminal disposed on the opposite side of the semiconductor element from the circuit board; and
a bonding wire connecting the semiconductor element and the control signal terminal.

2. The semiconductor device according to claim 1, further comprising:
a resin member sealing the semiconductor element, the circuit board, and at least a connection between the bonding wire and the control signal terminal.

3. The semiconductor device according to claim 1, further comprising:
a control board controlling the semiconductor element, wherein the control board is disposed on the opposite side of the semiconductor element from the circuit board and connected to the control signal terminal.

4. The semiconductor device according to claim 1, further comprising:
a power terminal that is connected to the semiconductor element on the opposite side thereof from the circuit board and between the semiconductor element and the control signal terminal.
